(19) United States
(12) Patent Application Publication
(10) Pub. No.: US 2025/0160127 A1
(43) Pub. Date: May 15, 2025

(54) DISPLAY DEVICE AND METHOD FOR FABRICATION THEREOF

(71) Applicant: Samsung Display Co., LTD., Yongin-si (KR)

(72) Inventors: Hyun Eok SHIN, Yongin-si (KR); Joon Yong PARK, Yongin-si (KR); Sung Hoon YANG, Yongin-si (KR)

(73) Assignee: Samsung Display Co., LTD., Yongin-si (KR)

(21) Appl. No.: 18/761,967

(22) Filed: Jul. 2, 2024

(30) Foreign Application Priority Data
Nov. 13, 2023 (KR) 10-2023-0156170

(51) Int. Cl. H10K 59/122; H10K 59/12

(52) U.S. Cl. CPC H10K 59/122; H10K 59/1201

(57) ABSTRACT

A display device includes a pixel electrode disposed on a substrate, a pixel defining layer disposed on the substrate and exposing the pixel electrode, a light emitting layer disposed on the pixel electrode, a common electrode disposed on the light emitting layer, a first bank disposed on the pixel defining layer, and a second bank disposed on the first bank and having a side protruding more than a side of the first bank. The second bank includes a first layer having a modulus less than about 300 GPa and a second layer having a modulus equal to or greater than about 300 GPa.

### CROSS-REFERENCE TO RELATED APPLICATION(S)

This application claims priority to and benefits of Korean Patent Application No. 10-2023-0156170 under 35 U.S.C. 119, filed on Nov. 13, 2023, in the Korean Intellectual Property Office (KIPO), the contents of which are incorporated herein by reference.

### BACKGROUND

### 1. Technical Field

The disclosure relates to a display device and a method for fabrication thereof.

### 2. Description of the Related Art

With the advancement of the information age, the demand for a display device for displaying an image has increased with various forms. For example, the display device has been applied to various electronic devices such as a smart phone, a digital camera, a laptop computer, a navigator and a smart television. The display device may be a flat panel display device such as a liquid crystal display device, a field emission display device, and an organic light emitting display device. Among such flat panel display devices, the light emitting display device includes a light emitting element in which each of pixels of a display panel may self-emit light, thereby displaying an image even a separate light emitting device that provides light.

Recently, the display device has been applied to a glasses-type device to provide virtual reality and augmented reality. In order to be applied to the glasses-type device, the display device is implemented at a very small size of 2 inches or less, but the display device should have high pixel integration to implement high resolution. For example, the display device may have high pixel integration of 400 pixels per inch (PPI) or more.

As described above, the display device is implemented at a very small size, but an area of a light emission area in which a light emitting element is disposed is reduced in case that the display device has high pixel integration. Therefore, it may be difficult to implement light emitting elements separated for each light emission area by a mask process.

### SUMMARY

An object of the disclosure is to provide a display device that may form light emitting elements separated for each light emission area without a mask process.

Another object of the disclosure is to provide a display device in which a light emission deviation that may occur in each pixel is reduced.

The objects of the disclosure are not limited to those mentioned above and additional objects of the disclosure, which are not mentioned herein, will be clearly understood by those skilled in the art from the following description of the disclosure.

According to an embodiment of the disclosure, a display device may include a pixel electrode disposed on a substrate, a pixel defining layer disposed on the substrate and exposing the pixel electrode, a light emitting layer disposed on the pixel electrode, a common electrode disposed on the light emitting layer, a first bank disposed on the pixel defining layer, and a second bank disposed on the first bank and having a side protruding more than a side of the first bank. The second bank may include a first layer having a modulus less than about 300 GPa and a second layer having a modulus equal to or greater than about 300 GPa.

A difference between the modulus of the first layer of the second bank and the modulus of the second layer of the second bank may be in a range of about 350 GPa to about 800 GPa.

The side of the first layer of the second bank and the side of the second layer of the second bank may be aligned.

A sum of thicknesses of the first layer and the second layer may be less than about 2400 Å.

A thickness of the first layer of the second bank may be about 0.5 to about 2 times of a thickness of the second layer of the second bank.

A thickness of the first layer of the second bank may be in a range of about 500 Å to about 1200 Å, and a thickness of the second layer of the second bank may be in a range of about 300 Å to about 1200 Å.

The first layer may include titanium, and the second layer may include diamond-like carbon (DLC) or tungsten carbide.

The first layer of the second bank may be disposed on the first bank, and the second layer of the second bank may be disposed on the first layer of the second bank.

The second bank may further include a third layer disposed between the first layer and the second layer and may contain titanium oxide.

A thickness of the third layer of the second bank may be less than a thickness of the first layer and the second layer of the second bank.

A thickness of the third layer of the second bank may be in a range of about 50 Å to about 200 Å.

The second layer of the second bank may be disposed on the first bank, and the first layer of the second bank may be disposed on the second layer of the second bank.

The display device may further include a first inorganic layer disposed on an upper surface and a lower surface of the second bank and on the first common electrode.

The first inorganic layer may be spaced apart from the upper surface of the second bank.

The display device may further include an organic encapsulation layer disposed in a space between the first inorganic layer and the upper surface of the second bank.

The second bank, the organic encapsulation layer, and the first inorganic layer may be sequentially stacked in an area overlapping the second bank and the first inorganic layer in a plan view.

According to an embodiment of the disclosure, a method for fabricating a display device may include forming a plurality of pixel electrodes spaced apart from each other and a pixel defining layer exposing the plurality of pixel electrodes, forming a first bank material layer on the pixel defining layer, forming a multi-layered second bank material layer on the first bank material layer, etching a portion of the multi-layered second bank material layer and the first bank material layer, etching a side of the first bank material layer to expose a lower surface of multi-layered the second bank material layer, forming a light emitting layer on one of the plurality of pixel electrodes, forming a light emitting pattern layer on the multi-layered second bank material layer, forming a common electrode on the light emitting layer, forming an electrode pattern layer on the light emitting pattern layer, forming an inorganic material layer on the electrode pattern layer, etching a portion of the inorganic material layer, and etching the light emitting pattern layer and the electrode pattern layer to expose the multi-layered second bank material layer.

The forming of the multi-layered second bank material layer on the first bank material layer may include forming a first material layer containing titanium; and forming a second material layer containing diamond-like carbon (DLC) or tungsten carbide.

The etching of the portion of the multi-layered second bank material layer and the first bank material layer may include forming a mask pattern on the multi-layered second bank material layer; and etching the multi-layered second bank material layer and the first bank material layer not covered by the mask pattern through a dry-etching process.

The etching of the light emitting pattern layer and the electrode pattern layer may include removing the light emitting pattern layer and the electrode pattern layer between the multi-layered second bank material layer and the inorganic material layer.

In the display device according to one embodiment and a method for fabricating the same, by including multiple layers of second banks, damage of the light emitting element due to an etchant or moisture may be avoided, so that a luminance difference between the light emitting elements may be reduced.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to one embodiment;

FIG. 2 is a schematic cross-sectional view illustrating the display device of FIG. 1;

FIG. 3 is a plan view illustrating an arrangement of light emitting elements, lower inorganic encapsulation layers and a second bank of a display device according to one embodiment;

FIG. 4 is a schematic cross-sectional view illustrating a portion of a display device according to one embodiment;

FIG. 5 is an enlarged view illustrating area A10 of FIG. 4;

FIG. 6 is an enlarged view illustrating area A10 according to another embodiment;

FIG. 7 is a schematic cross-sectional view of a display device including a second bank of a single layer where a second bank is bent;

FIG. 8 is an enlarged view of a display device according to still another embodiment; and

FIGS. 9 to 16 are schematic cross-sectional views sequentially illustrating a method for fabricating a display device according to one embodiment.

### DETAILED DESCRIPTION OF THE DISCLOSURE

The disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

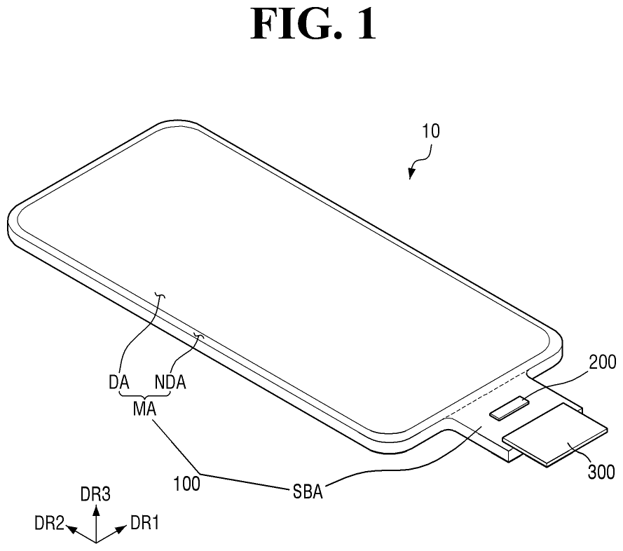

FIG. 1 is a perspective view illustrating a display device according to one embodiment.

Referring to FIG. 1, a display device 10 according to one embodiment may be included in an electronic device to provide a screen displayed in the electronic device. The electronic device may refer to all electronic devices that provide a display screen. For example, a television, a laptop computer, a monitor, an advertising board, Internet of Things, a mobile phone, a smart phone, a tablet personal computer (PC), an electronic watch, smart glasses, a smart watch, a watch phone, a head mounted display, a mobile communication terminal, an electronic diary, an electronic book, a portable multimedia player (PMP), a navigator, a game machine, a digital camera, a camcorder and the like, which provide a display screen, may be included in the electronic device.

Various modifications may be made in a shape of the display device 10. For example, the display device 10 may have a shape similar to a rectangular shape having a short side in a first direction DR1 and a long side in a second direction DR2. A corner where the short side in the first direction DR1 and the long side in the second direction DR2 meets may be rounded with a curvature, but is not limited thereto and may formed at a right angle. A planar shape of the display device 10 may be similar to other polygonal shape, a circular shape or an oval shape without being limited to the rectangular shape.

The display device 10 may include a display panel 100, a display driver 200, a circuit board 300, and a touch driver 400.

The display panel 100 may include a main area MA and a sub-area SBA.

The main area MA may include a display area DA having pixels for displaying an image, and a non-display area NDA disposed adjacent to the display area DA. The display area DA may emit light from multiple light emission areas or multiple opening areas. For example, the display panel 100 may include a pixel circuit including switching elements, a pixel defining layer defining a light emission area or an opening area, and a self-light emitting element.

For example, the self-light emitting element may include at least one of an organic light emitting diode including an organic light emitting layer, a quantum dot LED including a quantum dot light emitting layer, an inorganic LED including an inorganic semiconductor, and a micro LED.

Multiple pixels, multiple scan lines, multiple data lines and multiple power lines may be disposed in the display area DA. Each of the pixels may be a minimum unit for emitting light, and each of the above-described self-light emitting elements may be disposed in each pixel. The scan lines may supply a scan signal received from the scan driver to the pixels. The data lines may supply a data voltage received from the display driver 200 to the pixels. The power lines may supply a power voltage received from the display driver 200 to the pixels.

The non-display area NDA may be an outer area of the display area DA. The non-display area NDA may be defined as an edge area of the main area MA of the display panel 100. The non-display area NDA may include a scan driver for supplying scan signals to scan lines and fan-out lines for connecting the display driver 200 with the display area DA.

The sub-area SBA may be extended from a side of the main area MA. The sub-area SBA may include a flexible material capable of being subjected to bending, folding, rolling and the like. For example, in case that the sub-area SBA is bent, the sub-area SBA may overlap the main area MA in a thickness direction (third direction DR3). The sub-area SBA may include a display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply the power voltage to the power line, and supply scan control signals to the scan driver. The display driver 200 may be formed of an integrated circuit (IC), and may be packaged on the display panel 100 by a chip on glass (COG) mode, a chip on plastic (COP) mode or an ultrasonic bonding mode. For example, the display driver 200 may be disposed in the sub-area SBA, and may overlap the main area MA in the thickness direction (third direction DR3) by bending of the sub-area SBA. In another embodiment, the display driver 200 may be packaged on the circuit board 300.

The circuit board 300 may be attached onto the pad portion of the display panel 100 using an anisotropic conductive film (ACF). Lead lines of the circuit board 300 may be electrically connected to the pad portion of the display panel 100. The circuit board 300 may be a flexible printed circuit board, a printed circuit board or a flexible film such as a chip on film.

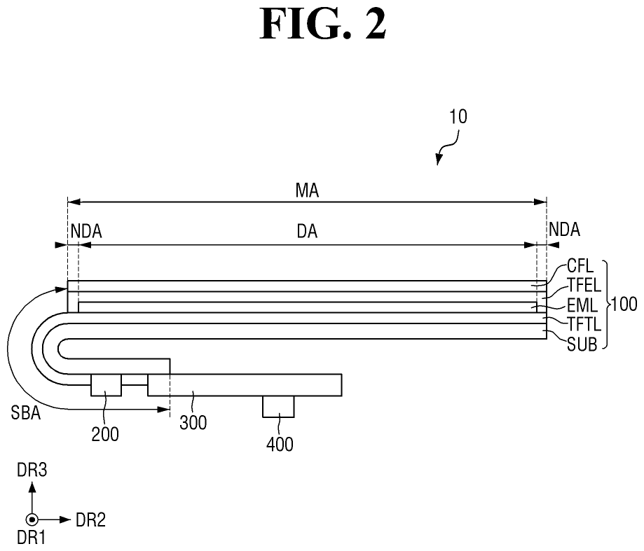

FIG. 2 is a schematic cross-sectional view illustrating the display device of FIG. 1. In detail, FIG. 2 relates to a side of the display device of FIG. 1, which is folded.

Referring to FIG. 2, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate capable of being subjected to bending, folding, rolling or the like. For example, the substrate SUB may include a polymer resin including polyimide (PI), but the disclosure is not limited thereto. In another embodiment, the substrate SUB may include a glass material or a metal material.

The thin film transistor layer TFTL may be disposed on the substrate SUB. The thin film transistor layer TFTL may include multiple thin film transistors constituting a pixel circuit of pixels. The thin film transistor layer TFTL may further include scan lines, data lines, power lines, scan control lines, fan-out lines for connecting the display driver 200 with the data lines, and lead lines for connecting the display driver 200 with the pad portion. Each of the thin film transistors may include a semiconductor area, a source electrode, a drain electrode and a gate electrode. For example, in case that the scan driver is formed at a side of the non-display area NDA of the display panel 100, the scan driver may include thin film transistors.

The thin film transistor layer TFTL may be disposed in the display area DA, the non-display area NDA and the sub-area SBA. The thin film transistors, the scan lines, the data lines and the power lines of respective pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include multiple light emitting elements that include a first electrode, a second electrode and a light emitting layer to emit light, and a pixel defining layer that defines pixels. The light emitting elements of the light emitting element layer EML may be disposed in the display area DA.

In one embodiment, the light emitting layer may be an organic light emitting layer that includes an organic material. The light emitting layer may include a hole transporting layer, an organic light emitting layer and an electron transporting layer. In case that the first electrode receives a voltage from the thin film transistor of the thin film transistor layer TFTL and the second electrode receives a cathode voltage, holes and electrons may move to the organic light emitting layer through the hole transporting layer and the electron transporting layer, respectively and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and sides of the light emitting element layer EML and protect the light emitting element layer EML. The thin film encapsulation layer TFEL may include at least one inorganic film and at least one organic film to encapsulate the light emitting element layer EML.

The color filter layer CFL may be disposed on the thin film encapsulation layer TFEL. The color filter layer CFL may include multiple color filters respectively corresponding to the light emission areas. Each of the color filters may selectively transmit light of a particular wavelength and block or absorb light of another wavelength. The color filter layer CFL may absorb a portion of light introduced from the outside of the display device 10 to reduce reflective light due to external light. Therefore, the color filter layer CFL may prevent distortion of a color, which is caused by external light reflection, from occurring.

Since the color filter layer CFL is directly disposed on the thin film encapsulation layer TFEL, the display device 10 may not require a separate substrate for the color filter layer CFL. Therefore, a thickness of the display device 10 may be relatively reduced.

In some embodiments, the display device 10 may further include an optical device. The optical device may emit or receive light of an infrared, ultraviolet or visible band. For example, the optical device may be an optical sensor for sensing light incident on the display device 10, such as a proximity sensor, an illuminance sensor, a camera sensor, a fingerprint sensor or an image sensor.

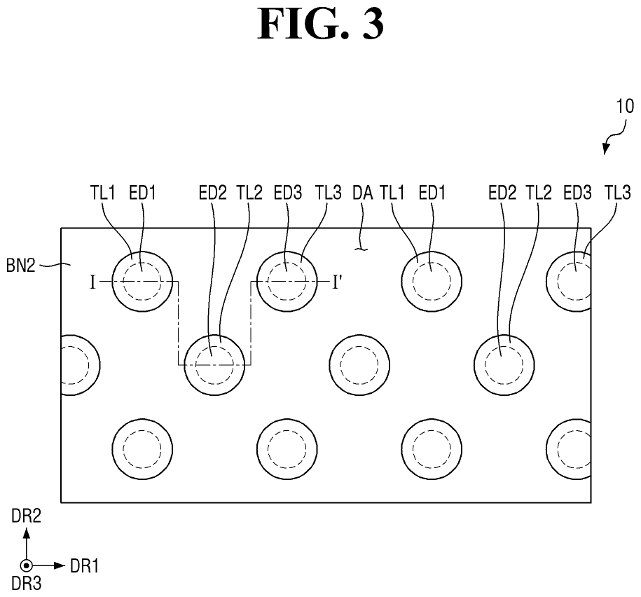

FIG. 3 is a plan view illustrating a portion of a display device according to one embodiment. FIG. 3 is a plan view illustrating arrangement of light emitting elements ED1, ED2 and ED3, lower inorganic encapsulation layers TL1, TL2 and TL3 and a second bank BN2 in a display area DA of a display device 10.

Referring to FIG. 3, the second bank BN2 may expose a portion of the display area DA while covering another portion of the display area DA. An opening (a dotted area in FIG. 3) may be formed in the area exposed without being covered by the second bank BN2, and the light emitting elements ED1, ED2 and ED3 may be disposed in each opening. The lower inorganic encapsulation layers TL1, TL2 and TL3 may cover a boundary portion of the opening on the second bank BN2, and may cover the light emitting elements ED1, ED2 and ED3 in the opening.

Although the area exposed without being covered by the second bank BN2 is shown in FIG. 3 as having a circular shape in a plan view, the shape may be a polygonal shape such as a triangular shape, a quadrangular shape or a hexagonal shape, and a shape of the lower inorganic encapsulation layers TL1, TL2 and TL3 covering the exposed area and its periphery may be also modified. A portion of the lower inorganic encapsulation layers TL1, TL2 and TL3 may be disposed at a level higher than the second bank BN2, and the light emitting elements ED1, ED2 and ED3 may be disposed at a level lower than the second bank BN2.

The light emitting elements ED1, ED2 and ED3 may be arranged in a PenTile™ type in a plan view, for example, a diamond PenTile™ type. For example, the first light emitting element ED1 and the third light emitting element ED3 may be spaced apart from each other in the first direction DR1, and may be alternately disposed in the first direction DR1 and the second direction DR2. The second light emitting element ED2 may be spaced apart from another adjacent second light emitting element ED2 in the first direction DR1 and the second direction DR2. The second light emitting element ED2 and the first light emitting element ED1 or the second light emitting element ED2 and the third light emitting element ED3 may be alternately disposed along a direction on a plane defined by the first direction DR1 and the second direction DR2. The shapes and arrangements of the areas exposed without being covered by the second bank BN2 and the light emitting elements are not limited to FIG. 3.

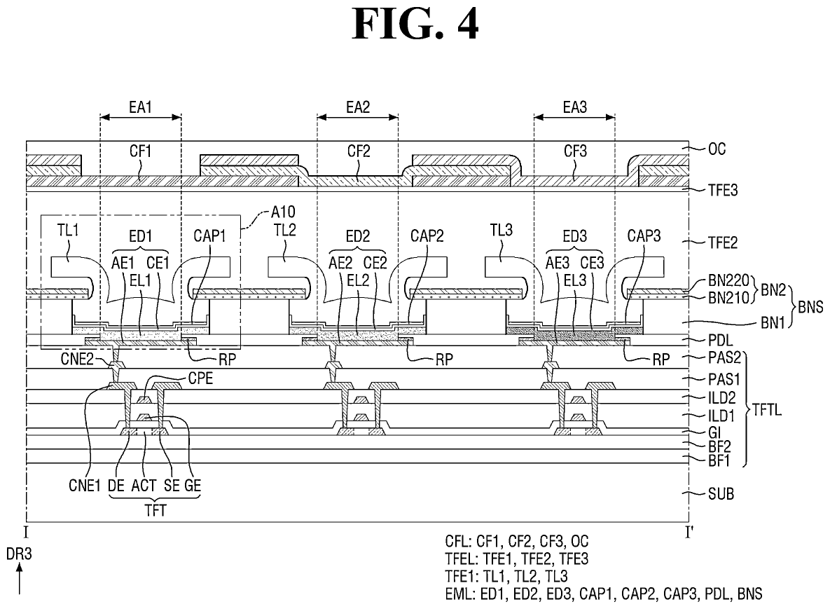

FIG. 4 is a schematic cross-sectional view illustrating a portion of a display device according to one embodiment. In detail, FIG. 4 is a schematic cross-sectional view taken along line I-I′ of FIG. 3. FIG. 4 schematically illustrates a cross-section of a substrate SUB, a thin film transistor layer TFTL, a light emitting element layer EML, a thin film encapsulation layer TFEL and a color filter layer CFL.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of the air or moisture. For example, the first buffer layer BF1 may include multiple inorganic films that are alternately stacked each other.

A lower metal layer may be disposed on the first buffer layer BF1. For example, the lower metal layer may be formed of a single layer or multi-layer including at least one of molybdenum (Mo), aluminum (Al), chromium (Cr), gold (Au), titanium (Ti), nickel (Ni), neodymium (Nd), copper (Cu), and an alloy thereof.

The second buffer layer BF2 may cover the first buffer layer BF1 and the lower metal layer. The second buffer layer BF2 may include an inorganic film capable of preventing permeation of the air or moisture. For example, the second buffer layer BF2 may include multiple inorganic films that are alternately stacked each other.

The thin film transistor TFT may be disposed on the second buffer layer BF2, and may constitute a pixel circuit of each of the pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction DR3, and may be insulated from the gate electrode GE by the gate insulating layer GI. A portion of the semiconductor layer ACT may form the source electrode SE and the drain electrode DE by conductorizing a material of the semiconductor layer ACT.

The gate electrode GE may be disposed on the gate insulating layer GI. The gate electrode GE may overlap the semiconductor layer ACT in the thickness direction DR3, and the gate insulating layer GI may be interposed between the electrode GE and the semiconductor layer ACT.

The gate insulating layer GI may be disposed on the semiconductor layer ACT. For example, the gate insulating layer GI may cover the semiconductor layer ACT and the second buffer layer BF2, and may insulate the semiconductor layer ACT from the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI. The first connection electrode CNE1 may be disposed on the second interlayer insulating layer ILD2. The first connection electrode CNE1 may electrically connect the drain electrode DE of the thin film transistor TFT with the second connection electrode CNE2. The first connection electrode CNE1 may be inserted into the contact holes formed in the second interlayer insulating layer ILD2, the first interlayer insulating layer ILD1 and the gate insulating layer GI to contact the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 with pixel electrodes AE1, AE2 and AE3 of the light emitting element ED. The second connection electrode CNE2 may be inserted into the contact hole formed in the first passivation layer PAS1 to contact the first connection electrode CNE1.

The second passivation layer PAS2 may cover the second connection electrode CNE2 and the first passivation layer PAS1. The second passivation layer PAS2 may include a contact hole through which the pixel electrodes AE1, AE2 and AE3 of the light emitting element ED pass.

The light emitting element layer EML may be disposed on the thin film transistor layer TFTL. The light emitting element layer EML may include a light emitting element ED, a capping layer CAP, a pixel defining layer PDL, and a bank structure BNS. The light emitting element ED may include pixel electrodes AE1, AE2 and AE3, light emitting layers EL1, EL2 and EL3, and common electrodes CE1, CE2 and CE3.

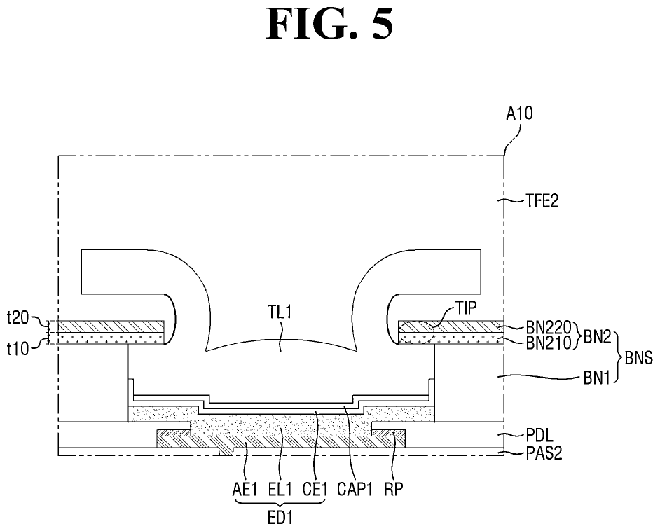

FIG. 5 is an enlarged view illustrating the first emission area of FIG. 4, specifically area A10.

Referring to FIG. 5 in conjunction with FIG. 4, the display device 10 may include multiple emission areas EA1, EA2 and EA3 disposed in the display area DA. The emission areas EA1, EA2 and EA3 may include areas in which light is emitted from the light emitting elements ED1, ED2 and ED3 to pass through the color filter layer CFL in the third direction DR3, and the pixel electrodes AE1, AE2 and AE3, the light emitting layers EL1, EL2 and EL3 and the common electrodes CE1, CE2 and CE3 may be sequentially stacked in the light emitting elements ED1, ED2 and ED3. The emission areas EA1, EA2 and EA3 may include a first emission area EA1, a second emission area EA2 and a third emission area EA3, which are spaced apart from one another and emit light of the same color or different colors.

In one embodiment, areas or sizes of the first to third emission areas EA1, EA2 and EA3 may be the same in a plan view. For example, in the display device 10, the first emission area EA1, the second emission area EA2 and the third emission area EA3 may have a same size, but the disclosure is not limited thereto. In the display device 10, the first to third emission areas EA1, EA2 and EA3 may have different areas or sizes in a plan view. For example, the size of the second emission area EA2 may be greater than the size of each of the first emission area EA1 and the third emission area EA3, and the size of the third emission area EA3 may be greater than the size of the first emission area EA1 in a plan view. The intensity of light emitted from the corresponding emission areas EA1, EA2 and EA3 may be varied depending on the sizes of the emission areas EA1, EA2 and EA3, and the sizes of the emission areas EA1, EA2 and EA3 may be adjusted so that a color of an image displayed on the display device 10 may be controlled. In the embodiment of FIG. 4, the sizes of the emission areas EA1, EA2 and EA3 are illustrated as being the same as one another, but the disclosure is not limited thereto.

In the display device 10, one first emission area EA1, one second emission area EA2 and one third emission area EA3, which are disposed to be adjacent to one another, may form one pixel group. One pixel group may include the emission areas EA1, EA2 and EA3 that emit light of different colors, thereby representing a white gray scale, but the disclosure is not limited thereto. A combination of the emission areas EA1, EA2 and EA3 constituting one pixel group may be variously modified depending on the arrangement of the emission areas EA1, EA2 and EA3 and the colors of the light emitted from the emission areas EA1, EA2 and EA3.

The openings formed in the bank structure BNS of the light emitting element layer EML may be defined along a boundary of the bank structure BNS. The first bank BN1 and the second bank BN2 of the bank structure BNS may surround the emission areas EA1, EA2 and EA3 in a plan view. Each of the openings may include one of the first to third emission areas EA1, EA2 and EA3.

The display device 10 may include multiple light emitting elements ED1, ED2 and ED3 respectively disposed in corresponding emission areas EA1, EA2 and EA3. The light emitting elements ED1, ED2 and ED3 may include a first light emitting element ED1 disposed in the first emission area EA1, a second light emitting element ED2 disposed in the second emission area EA2, and a third light emitting element ED3 disposed in the third emission area EA3.

Each of the light emitting elements ED1, ED2 and ED3 may include pixel electrodes AE1, AE2 and AE3, light emitting layers EL1, EL2 and EL3 and common electrodes CE1, CE2 and CE3, and the light emitting elements ED1, ED2 and ED3 respectively disposed in the emission areas EA1, EA2 and EA3 may emit light of different colors depending on materials of the light emitting layers EL1, EL2 and EL3. For example, the first light emitting element ED1 disposed in the first emission area EA1 may emit first light of a first color, which has a peak wavelength in a range of about 610 nm to about 650 nm, the second light emitting element ED2 disposed in the second emission area EA2 may emit second light of a green color, which has a peak wavelength in a range of about 510 nm to about 550 nm, and the third light emitting element ED3 disposed in the third emission area EA3 may emit third light of a blue color, which has a peak wavelength in a range of about 440 nm to about 480 nm. The first to third emission areas EA1, EA2 and EA3 constituting one pixel may include the light emitting elements ED1, ED2 and ED3 for emitting light of different colors to implement a white gray scale. In another embodiment, as the light emitting layers EL1, EL2 and EL3 may include two or more materials for emitting light of different colors, one light emitting layer may emit mixture light. For example, the light emitting layers EL1, EL2 and EL3 may include a material for emitting red light and a material for emitting green light together to emit yellow light, or may include a material for emitting red light, a material for emitting green light, and a material for emitting blue light to emit white light.

The pixel electrodes AE1, AE2 and AE3 may be disposed on the second passivation layer PAS2. The pixel electrodes AE1, AE2 and AE3 may be disposed in the emission areas EA1, EA2 and EA3, respectively. The pixel electrodes AE1, AE2 and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2 and the third pixel electrode AE3 may be spaced apart from one another on the second passivation layer PAS2.

The pixel electrodes AE1, AE2 and AE3 may be electrically connected to the drain electrode DE of the thin film transistor TFT through the first and second connection electrodes CNE1 and CNE2. Edges of the pixel electrodes AE1, AE2 and AE3 may be covered by the pixel defining layer PDL, so that the first to third pixel electrodes AE1, AE2 and AE3 may be insulated from one another.

The pixel electrodes AE1, AE2 and AE3 may include a transparent electrode material and/or a conductive metal material. For example, the pixel electrodes AE1, AE2 and AE3 may include a metal such as silver (Ag), copper (Cu), aluminum (Al), nickel (Ni), lanthanum (La), titanium (Ti), titanium nitride (TiN), and a combination thereof. For example, the pixel electrodes AE1, AE2 and AE3 may include an electrode material such as Indium Tin Oxide (ITO), Indium Zinc Oxide (IZO), Indium Tin Zinc Oxide (ITZO), and a combination thereof. The pixel electrodes AE1, AE2 and AE3 may have a multi-layered structure of a transparent electrode material and a conductive metal material.

The pixel defining layer PDL may be disposed on the second passivation layer PAS2, a residual pattern RP and the pixel electrodes AE1, AE2 and AE3. The pixel defining layer PDL may be disposed on the second passivation layer PAS2, and may cover sides of the pixel electrodes AE1, AE2 and AE3 and the residual pattern RP to expose a portion of upper surfaces of the pixel electrodes AE1, AE2 and AE3. For example, the pixel defining layer PDL may expose a portion of the first pixel electrode AE1 in the first emission area EA1 in a plan view, and the first light emitting layer EL1 may be disposed directly on the first pixel electrode AE1.

The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but the disclosure is not limited thereto.

According to one embodiment, the pixel defining layer PDL may be disposed on the pixel electrodes AE1, AE2 and AE3, and may be spaced apart from the upper surfaces of the pixel electrodes AE1, AE2 and AE3. The pixel defining layer PDL may not directly contact the upper surfaces of the pixel electrodes AE1, AE2 and AE3 while partially overlapping the upper surfaces of the pixel electrodes AE1, AE2 and AE3 in the thickness direction DR3 of the substrate SUB, and the residual pattern RP may be disposed between the pixel defining layer PDL and the pixel electrodes AE1, AE2 and AE3. However, the pixel defining layer PDL may direly contact the sides of the pixel electrodes AE1, AE2 and AE3. Sides of the pixel defining layer PDL may be more protruded toward the emission areas EA1, EA2 and EA3 than sides of the second bank BN2.

The residual pattern RP may be disposed on the edge of each of the pixel electrodes AE1, AE2 and AE3. The pixel defining layer PDL may not directly contact the upper surfaces of the pixel electrodes AE1, AE2 and AE3 due to the residual pattern RP. In a manufacturing process of the display device 10, a portion of a sacrificial layer disposed on the pixel electrodes AE1, AE2 and AE3 may be removed so that the residual pattern RP may be formed. The residual pattern RP may include a metal or an oxide semiconductor material. In the drawing, sides of the residual pattern RP, which are directed toward the light emission areas EA1, EA2 and EA3, are illustrated as being aligned with the sides of the pixel defining layer PDL, but the disclosure is not limited thereto. In another embodiment, the sides of the residual pattern RP may be more protruded than the sides of the pixel defining layer PDL toward the light emission areas EA1, EA2 and EA3, or may be more recessed than the sides of the pixel defining layer PDL. The sides of the pixel defining layer PDL may be the outermost sides directed toward the light emission areas EA1, EA2 and EA3.

The light emitting layers EL1, EL2 and EL3 may be disposed on the pixel electrodes AE1, AE2 and AE3. The light emitting layers EL1, EL2 and EL3 may be organic light emitting layers made of an organic material, and may be formed on the pixel electrodes AE1, AE2 and AE3 through a deposition process. The light emitting layers EL1, EL2 and EL3 may have a multi-layered structure, and each of a hole injection material, a hole transporting material, a light emitting material, an electron transporting material and/or an electron injection material may constitute a layer. In case that the thin film transistor TFT applies a voltage to the pixel electrodes AE1, AE2 and AE3 of the light emitting elements ED1, ED2 and ED3 and the common electrodes CE1, CE2 and CE3 of the light emitting elements ED1, ED2 and ED3 receive a common voltage or a cathode voltage, holes and electrons may be injected and transported, and holes and electrons may be combined with each other in the light emitting layers EL1, EL2 and EL3 to emit light.

The light emitting layers EL1, EL2 and EL3 may include a first light emitting layer EL1, a second light emitting layer EL2 and a third light emitting layer EL3, which are disposed in the different emission areas EA1, EA2 and EA3, respectively. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The light emitting layers EL1, EL2 and EL3 may emit light of different colors, respectively, or one of the light emitting layers EL1, EL2 and EL3 may emit mixture light. In one embodiment, the first light emitting layer EL1 may emit red light, the second light emitting layer EL2 may emit green light, and the third light emitting layer EL3 may emit blue light. In another embodiment, the first light emitting layer EL1 may emit yellow light, which is mixture light of red light and green light, and the second light emitting layer EL2 may emit blue light. In another embodiment, the first light emitting layer EL1 may emit white light, which is mixture light of red light, green light and blue light.

The light emitting layers EL1, EL2 and EL3 may be disposed on an upper surface of the pixel defining layer PDL. In one embodiment, the light emitting layers EL1, EL2 and EL3 may be disposed in spaces between the pixel electrodes AE1, AE2 and AE3 and the pixel defining layer PDL. In one embodiment, the light emitting layers EL1, EL2 and EL3 may be in contact with the pixel defining layer PDL, the residual pattern RP and the pixel electrodes AE1, AE2 and AE3.

The common electrodes CE1, CE2 and CE3 may be disposed on the light emitting layers EL1, EL2 and EL3. The common electrodes CE1, CE2 and CE3 may include a transparent conductive material so that light generated from the light emitting layers EL1, EL2 and EL3 may be emitted. The common electrodes CE1, CE2 and CE3 may receive a common voltage or a low potential voltage. In case that the pixel electrodes AE1, AE2 and AE3 receive a voltage corresponding to the data voltage and the common electrodes CE1, CE2 and CE3 receive a low potential voltage, a potential difference may be formed between the pixel electrodes AE1, AE2 and AE3 and the common electrodes CE1, CE2 and CE3, and the light emitting layers EL1, EL2 and EL3 may emit light.

The common electrodes CE1, CE2 and CE3 may include a first common electrode CE1, a second common electrode CE2 and a third common electrode CE3, which are disposed in the different light emission areas EA1, EA2 and EA3, respectively. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2 and CE3 may be spaced apart from one another.

Capping layers CAP1, CAP2 and CAP3 may be disposed on the common electrodes CE1, CE2 and CE3. The capping layers CAP1, CAP2 and CAP3 may include an organic material or an inorganic insulating material and cover the light emitting elements ED1, ED2 and ED3. The capping layers CAP1, CAP2 and CAP3 may prevent the light emitting elements ED1, ED2 and ED3 from being damaged from the external air. In an embodiment, the capping layers CAP1, CAP2 and CAP3 may include an organic material such as a-NPD, NPB, TPD, m-MTDATA, Alq₃, LiF and/or CuPc or an inorganic material such as aluminum oxide, titanium oxide, tantalum oxide, hafnium oxide, zinc oxide, silicon oxide, silicon nitride and/or silicon oxynitride.

The capping layers CAP1, CAP2 and CAP3 may include a first capping layer CAP1, a second capping layer CAP2 and a third capping layer CAP3, which are disposed in the different emission areas EA1, EA2 and EA3, respectively. The first to third capping layers CAP1, CAP2 and CAP3 may be spaced apart from one another.

The display device 10 may include a multi-layer bank structure BNS disposed on the pixel defining layer PDL. The bank structure BNS may have a structure in which banks BN1 and BN2 containing different materials are sequentially stacked, include multiple openings including emission areas EA1, EA2 and EA3, and be arranged to overlap the light blocking layer BM in the third direction DR3 to be described below. The light emitting elements ED1, ED2 and ED3 of the display device 10 may overlap the opening of the bank structure BNS in the third direction DR3.

The bank structure BNS may include a first bank BN1 and a second bank BN2 sequentially stacked on the pixel defining layer PDL.

The first bank BN1 may be disposed on the pixel defining layer PDL. A side of the first bank BN1 may be more recessed than the side of the pixel defining layer PDL in the direction opposite to the direction facing the emission areas EA1, EA2 and EA3. The side of the first bank BN1 may be more recessed than the side of the second bank BN2, which will be described below, in the opposite direction to the direction facing the emission areas EA1, EA2 and EA3.

According to one embodiment, the first bank BN1 may include a metal material. In an embodiment, the first bank BN1 may include aluminum (Al), an oxide of aluminum (Al), or an alloy of aluminum (Al).

According to one embodiment, the common electrodes CE1, CE2, and CE3 may be in direct contact with the side of the first bank BN1. An end and another end of the common electrodes CE1, CE2, and CE3 may be in contact with the side of the first bank BN1. The common electrodes CE1, CE2, and CE3 of the different light emitting elements ED1, ED2, and ED3 may each be in direct contact with the first bank BN1, and the first bank BN1 may include a metal material so that each of the common electrodes CE1, CE2, and CE3 may be electrically connected to each other through the first bank BN1.

The light emitting layers EL1, EL2 and EL3 may be directly in contact with the sides of the first bank BN1. An area in which the common electrodes CE1, CE2 and CE3 are in contact with the sides of the first bank BN1 may be greater than an area in which the light emitting layers EL1, EL2 and EL3 are in contact with the sides of the first bank BN1. The common electrodes CE1, CE2 and CE3 may be disposed on the sides of the first bank BN1 to cover an area greater than the light emitting layers EL1, EL2 and EL3 or a higher position on the sides of the first bank BN1. Since the common electrodes CE1, CE2 and CE3 of the light emitting elements ED1, ED2 and ED3 are electrically connected to one another through the first bank BN1, it may be advantageous that the common electrodes CE1, CE2 and CE3 are to be in contact with the first bank BN1 in more areas.

The first bank BN1 may have the top surface that is higher than the common electrodes CE1, CE2, and CE3 and the capping layers CAP1, CAP2, and CAP3. The height from the substrate SUB to the top surface of the first bank BN1 may be greater than the height from the substrate SUB to the common electrodes CE1, CE2, and CE3.

The second bank BN2 may be disposed on the first bank BN1. The second bank BN2 may include a tip TIP that is an area more protruded than the first bank BN1. The sides of the second bank BN2 may be more protruded toward the emission areas EA1, EA2 and EA3 than the sides of the first bank BN1.

As the sides of the second bank BN2 have a shape more protruded toward the emission areas EA1, EA2 and EA3 than the sides of the first bank BN1, an undercut structure of the first bank BN1 may be formed below the tip TIP of the second bank BN2.

In the display device 10 according to one embodiment, the bank structure BNS may include a tip TIP protruded toward the emission areas EA1, EA2 and EA3 so that the light emitting layers EL1, EL2 and EL3 and the common electrodes CE1, CE2 and CE3, which are spaced apart from each other, may be formed by deposition and etching processes and not a mask process. Also, different layers may be individually formed in the different emission areas EA1, EA2 and EA3 by even the deposition process. For example, although the light emitting layers EL1, EL2 and EL3 of the light emitting elements ED1, ED2 and ED3 and the common electrodes CE1, CE2 and CE3 are formed by the deposition process without using a mask, deposited materials may be disconnected with the bank structure BNS interposed between the light emission areas EA1, EA2 and EA3 by the tip TIP of the second bank BN2 without being connected among the light emission areas EA1, EA2 and EA3. After a material for forming a specific layer is formed on an entire surface of the display device 10, different layers may be individually formed in the different emission areas EA1, EA2 and EA3 through a process of removing a layer formed in an undesired area through etching. In the display device 10, the different light emitting elements ED1, ED2 and ED3 may be respectively formed for the emission areas EA1, EA2 and EA3 through deposition and etching processes without using a mask process, unnecessary elements in the display device 10 may be omitted, and a size of the non-display area NDA may be minimized.

The second bank BN2 may include first layers BN210 and BN211 having a modulus of less than or equal to about 300 GPa, and second layers BN220 and BN221 having a modulus of greater than or equal to about 300 GPa. In this specification, modulus may mean Young's modulus and may be a value measured by ASTM E 11-97.

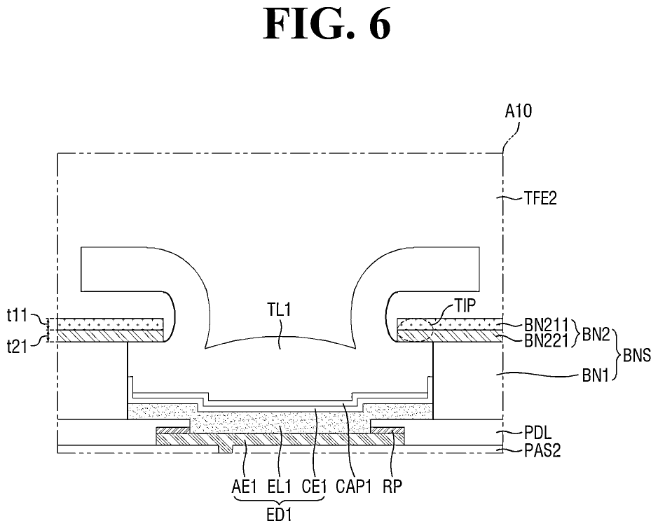

FIG. 5 is an enlarged view of the first emission area EA1 of the display device 10 according to one embodiment, and FIG. 6 is an enlarged view illustrating area A10 of the first emission area EA1 of the display device 10 according to another embodiment. In one embodiment, as shown in FIG. 5, the first layer BN210 of the second bank BN2 may be disposed on the first bank BN1, and the second layer BN220 of the second bank BN2 may be disposed on the first layer BN210 of the second bank BN2. In another embodiment, as shown in FIG. 6, the second layer BN221 of the second bank BN2 may be disposed on the first bank BN1, and the first layer BN211 of the second bank BN2 may be disposed on the second layer BN221 of the second bank BN2.

In an embodiment, the difference between the moduli of the first layers BN210 and BN211 of the second bank BN2 and the moduli of the second layers BN220 and BN221 of the second bank BN2 may be in a range of about 350 GPa to about 800 GPa. In case that the difference in modulus between the two layers is within the above range, a tip TIP of the second bank BN2 may be prevented from bending or breaking.

In one embodiment, the modulus of the first layers BN210 and BN211 of the second bank BN2 may be less than or equal to about 200 GPa. For example, the modulus of the first layers BN210 and BN211 of the second bank BN2 may be less than or equal to about 150 GPa. In one embodiment, the modulus of the first layers BN210 and BN211 of the second bank BN2 may be greater than or equal to about 50 GPa. For example, the modulus of the first layers BN210 and BN211 of the second bank BN2 may be greater than or equal to about 100 GPa. The first layers BN210 and BN211 of the second bank BN2 may include titanium (Ti). The modulus of the first layers BN210 and BN211 of the second bank BN2 including titanium may be about 116 GPa.

In one embodiment, the modulus of the second layers BN220 and BN221 of the second bank BN2 may be greater than or equal to about 400 GPa. For example, the modulus of the second layers BN220 and BN221 of the second bank BN2 may be greater than or equal to about 500 GPa. In one embodiment, the modulus of the second layers BN220 and BN221 of the second bank BN2 may be less than or equal to about 1000 GPa. For example, the modulus of the second layers BN220 and BN221 of the second bank BN2 may be less than or equal to about 900 GPa. The second layers BN220 and BN221 of the second bank BN2 may include diamond-like carbon (DLC) or tungsten carbide. The modulus of the second layers BN220 and BN221 of the second bank including DLC may be in a range of about 500 GPa to about 900 GPa, and the modulus of the second layers BN220 and BN221 of the second bank BN2 including tungsten carbide may be in a range of about 530 GPa to about 700 GPa.

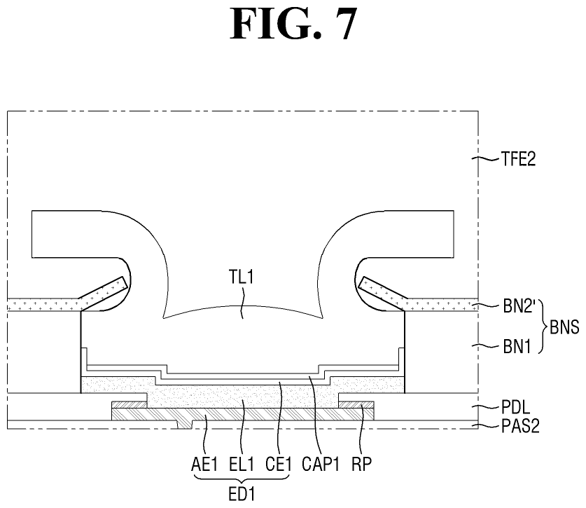

FIG. 7 is a schematic cross-sectional view of a display device including a second bank BN2′ of a single layer. The second bank BN2′ containing only titanium (Ti) may have a low modulus, so the tip TIP may bend during a cleaning or etching process. As the tip TIP is deformed, the second bank BN2′ may fall from the lower inorganic encapsulation layer TL1 or moisture permeation may occur. This may lead to a damage of the light emitting element ED1.

Since the second bank BN2 includes second layers BN220 and BN221 having a relatively large modulus value, the tip TIP may be robust against mechanical deformation. The second bank BN2 may include first layers BN210 and BN211 having a relatively small modulus value, so that the second bank BN2 may have a degree of ductility that does not break. The second bank BN2 may be resistant to deformation and cracks by including the first layers BN210 and BN211 and the second layers BN220 and BN221.

The sides of the first layers BN210 and BN211 of the second bank BN2 and the sides of the second layers BN220 and BN221 of the second bank BN2 may be aligned to form a flat surface. Although only the sides of the first layers BN210 and BN211 and the second layers BN220 and BN221 of the second bank BN2 are perpendicular to the substrate SUB in the drawing, the sides may be inclined with respect to the substrate SUB.

The sum of the thicknesses t10+t20 and t11+t21 of the first layers BN210 and BN211 and the second layers BN220 and BN221 of the second bank BN2 may be less than about 2400 Å. The second bank BN2 may include first layers BN210 and BN211 and second layers BN220 and BN221 having different moduli, and may have high strength and a thin thickness. In one embodiment, the sum of the thicknesses t10+t20 and t11+t21 of the first layers BN210 and BN211 and the second layers BN220 and BN221 of the second bank BN2 may be in a range of about 1000 Å to about 2000 Å.

The thicknesses t10 and t11 of the first layers BN210 and BN211 and the thicknesses t20 and t21 of the second layers BN220 and BN221 of the second bank BN2 may be appropriately adjusted according to needs. In one embodiment, the thicknesses t10 and t11 of the first layers BN210 and BN211 of the second bank BN2 may be about 0.5 to about 2 times of the thicknesses t20 and t21 of the second layers BN220 and BN221. In another embodiment, the thicknesses t10 and t11 of the first layers BN210 and BN211 of the second bank BN2 may be equal to or greater than the thicknesses t20 and t21 of the second layers BN220 and BN221.

In one embodiment, the thickness of each of the first layers BN210 and BN211 of the second bank BN2 may be in a range of about 500 Å to about 1200 Å. In another embodiment, the thickness of each of the first layers BN210 and BN211 of the second bank BN2 may be in a range of about 800 Å to about 1100 Å. In one embodiment, the thickness of each of the second layers BN220 and BN221 of the second bank BN2 may be in a range of about 300 Å to about 1200 Å. In another embodiment, the thickness of each of the second layers BN220 and BN221 of the second bank BN2 may be in a range of about 500 Å to about 1000 Å.

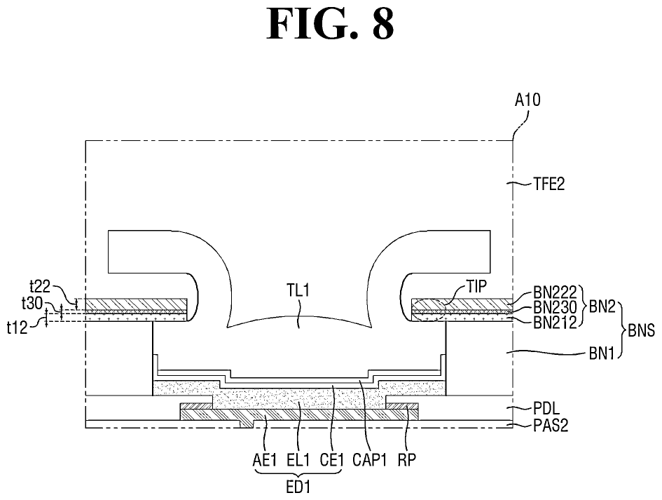

FIG. 8 is an enlarged view of a first emission area EA1 of a display device 10 according to still another embodiment. Compared to the display device in FIG. 5., the display device in FIG. 8 may further include a third layer BN230 between the first layer BN212 and the second layer BN222. Other configurations except the third layer BN230 are the same as described in FIG. 5.

The third layer BN230 of the second bank BN2 may be disposed between the first layers BN210 and BN211 and the second layers BN220 and BN221 of the second bank BN2, and defects due to arc that may occur while forming the first layers BN210 and BN211 and the second layers BN220 and BN221 may be prevented. The third layer BN230 of the second bank BN2 may include a high-resistance material. In one embodiment, the third layer BN230 of the second bank BN2 may include titanium oxide (TiOₓ).

A thickness t30 of the third layer BN230 of the second bank BN2 may be smaller than a thickness t12 of the first layer BN212 and a thickness t22 of the second layer BN222. In one embodiment, the thickness t30 of the third layer BN230 of the second bank BN2 may be in a range of about 50 Å to about 200 Å. Within the above range, the display element ED1 may not be damaged due to heat generation.

The thin film encapsulation layer TFEL may be disposed on the light emitting elements ED1, ED2 and ED3 and the bank structure BNS, and may cover the light emitting elements ED1, ED2 and ED3 and the bank structure BNS. The thin film encapsulation layer TFEL may include at least one inorganic film to prevent oxygen or moisture from being permeated into the light emitting element layer EML. The thin film encapsulation layer TFEL may include at least one organic film to protect the light emitting element layer EML from particles such as dust.

In an embodiment, the thin film encapsulation layer TFEL may include a lower inorganic encapsulation layer TFE1, an organic encapsulation layer TFE2 and an upper inorganic encapsulation layer TFE3, which are sequentially stacked.

Each of the lower inorganic encapsulation layer TFE1 and the upper inorganic encapsulation layer TFE3 may include an inorganic insulation material. For example, each of the lower inorganic encapsulation layer TFE1 and the upper inorganic encapsulation layer TFE3 may include at least one of silicon oxide, silicon nitride and silicon oxynitride, and may be, for example, aluminum oxide, titanium oxide, tantalum oxide, hafnium oxide, zinc oxide, silicon oxide, silicon nitride, and silicon oxynitride.

The organic encapsulation layer TFE2 may include a polymer-based material. For example, the organic encapsulation layer TFE2 may include at least one of an acrylic resin, an epoxy-based resin, polyimide, and polyethylene. For example, the organic encapsulation layer TFE2 may include an acrylic resin, for example, polymethyl methacrylate, polyacrylic acid, etc. The organic encapsulation layer TFE2 may be formed by hardening a monomer or coating a polymer.

The lower inorganic encapsulation layer TFE1 may be disposed on the light emitting elements ED1, ED2 and ED3, and the bank structure BNS. The lower inorganic encapsulation layer TFE1 may include a first inorganic layer TL1, a second inorganic layer TL2 and a third inorganic layer TL3, which are disposed to correspond to the light emission areas EA1, EA2 and EA3, respectively. Each of the first inorganic layer TL1, the second inorganic layer TL2 and the third inorganic layer TL3 may include an inorganic insulating material and cover the light emitting elements ED1, ED2 and ED3. The first inorganic layer TL1, the second inorganic layer TL2 and the third inorganic layer TL3 may prevent the light emitting elements ED1, ED2 and ED3 from being damaged from the external air.

The lower inorganic encapsulation layers TFE1: TL1, TL2 and TL3 may be formed through a chemical vapor deposition (CVD) method, and thus may be formed along a step difference of the deposited layers. For example, the first inorganic layer TL1, the second inorganic layer TL2 and the third inorganic layer TL3 may form a thin film even under the undercut due to the tip of the bank structure BNS. The lower inorganic encapsulation layers TL1, TL2 and TL3 may be disposed along the upper surface of the second bank BN2, the side surface of the first bank BN1, and the upper surface of the common electrodes CE1, CE2, and CE3.

The lower inorganic encapsulation layer TFE1 may include multiple spaced apart inorganic layers TL1, TL2, and TL3, and each of the inorganic layers TL1, TL2, and TL3 may be disposed in each of the emission areas EA1, EA2, and EA3. The first inorganic layer TL1 may not overlap the second light emitting element ED2 and the third light emitting element ED3 in the third direction DR3, but may be disposed only on the first light emitting element ED1 and the bank structure BNS in the periphery thereof. The second inorganic layer TL2 may not overlap the first light emitting element ED1 and the third light emitting element ED3 in the third direction DR3, but may be disposed only on the second light emitting element ED2 and the bank structure BNS in the periphery thereof. The third inorganic layer TL3 may not overlap the first light emitting element ED1 and the second light emitting element ED2 in the third direction DR3, but may be disposed only on the third light emitting element ED3 and the bank structure BNS in the periphery thereof.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2 and the third inorganic layer TL3 may be spaced apart from one another on the bank structure BNS.

The lower inorganic encapsulation layers TL1, TL2 and TL3 may be disposed on the upper surface of the light emitting elements ED1, ED2, and ED and the lower surface of the second bank BN2 in the periphery thereof, but may be separated from the upper surface of the second bank BN2. For example, the lower inorganic encapsulation layers TL1, TL2 and TL3 may have an undercut structure on the second bank BN2. The space between the lower inorganic encapsulation layers TL1, TL2 and TL3 and the upper surface of the second bank BN2 may be a space in which the materials of the light emitting layers EL1, EL2 and EL3, the common electrodes CE1, CE2, and CE3, and the capping layers CAP1, CAP2, and CAP3 deposited on the front surface is removed.

The organic encapsulation layer TFE2 may be disposed on the second bank BN2 and the lower inorganic encapsulation layers TL1, TL2 and TL3. A portion of the organic encapsulation layer TFE2 may be disposed in the space between the lower inorganic encapsulation layers TL1, TL2 and TL3 and the upper surface of the second bank BN2. In the area where the second bank BN2 and the lower inorganic encapsulation layers TL1, TL2 and TL3 overlap, the second bank BN2, the organic encapsulation layer TFE2, and the lower inorganic encapsulation layers TL1, TL2 and TL3 may be sequentially disposed. In the tip TIP area, the organic encapsulation layer TFE2 and the lower inorganic encapsulation layers TL1, TL2 and TL3 may be arranged sequentially on the second bank BN2, and the organic encapsulation layer TFE2 may be disposed on the top of the lower inorganic encapsulation layers TL1, TL2 and TL3. In other words, a portion of the organic encapsulation layer TFE2 may be disposed between the upper surface of the second bank BN2 and the lower inorganic encapsulation layers TL1, TL2 and TL3 on the tip TIP of the second bank BN2, and another portion of the organic encapsulation layer TFE2 may be disposed on top of the lower inorganic encapsulation layers TL1, TL2 and TL3.

In one embodiment, the entire upper surface of the second bank BN2 may be in contact with the organic encapsulation layer TFE2. The first lower surface of the lower inorganic encapsulation layers TL1, TL2 and TL3 may be a surface opposite to the upper surface of the second bank BN2, and the first lower surface of the lower inorganic encapsulation layers TL1, TL2 and TL3 may be in contact with the organic encapsulation layer TFE2.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride and/or silicon oxynitride.

A light blocking layer (not shown) may be disposed on the thin film encapsulation layer TFEL, but the disclosure is not limited thereto. The light blocking layer may be positioned between the light emission areas EA1, EA2 and EA3. The light blocking layer may include a light absorbing material. For example, the light blocking layer may include an inorganic black pigment or an organic black pigment. The inorganic black pigment may be carbon black, and the organic black pigment may include at least one of lactam black, perylene black, and aniline black, but the disclosure is not limited thereto. The light blocking layer may prevent color mixture from occurring due to permeation of visible light between the first to third light emission areas EA1, EA2 and EA3, thereby improving a color reproduction rate of the display device 10.

The display device 10 may include multiple color filters CF1, CF2 and CF3 disposed on the light emission areas EA1, EA2 and EA3. Each of the color filters CF1, CF2 and CF3 may include a filtering pattern area and a light blocking area. The filtering pattern area may overlap the light emission areas EA1, EA2 and EA3 or the opening of the bank structure BNS in the third direction DR3, and may form a light output area from which the light emitted from the light emission areas EA1, EA2 and EA3 is output. The light blocking area may be an area in which the color filters CF1, CF2 and CF3 are stacked so that light cannot be transmitted therethrough.

The color filters CF1, CF2 and CF3 may include a first color filter CF1, a second color filter CF2 and a third color filter CF3, which are disposed to correspond to the light emission areas EA1, EA2 and EA3, respectively. The color filters CF1, CF2 and CF3 may include a colorant such as a dye or pigment for absorbing light of another wavelength band other than light of a specific wavelength band, and may be disposed to correspond to colors of light emitted from the light emission areas EA1, EA2 and EA3. For example, the first color filter CF1 may be a red color filter disposed to overlap the first emission area EA1 in the third direction DR3, transmitting only first light of a red color. The second color filter CF2 may be a green color filter disposed to overlap the second emission area EA2 in the third direction DR3, transmitting only second light of a green color. The third color filter CF3 may be a blue color filter disposed to overlap the third emission area EA3 in the third direction DR3, transmitting only third light of a blue color.

The display device 10 may reduce the intensity of reflective light due to external light as the color filters CF1, CF2 and CF3 are disposed to overlap one another in the third direction DR3. Furthermore, a color sense of the reflective light due to external light may be controlled by adjustment of layout, shape, area and the like of the color filters CF1, CF2 and CF3 in a plan view.

An overcoat layer OC may be disposed on the color filters CF1, CF2 and CF3 and planarize upper ends of the color filters CF1, CF2 and CF3. The overcoat layer OC may be a colorless light-transmissive layer having no color of a visible light band. For example, the overcoat layer OC may include a colorless light-transmissive organic material such as an acrylic resin.

Hereinafter, a process of fabricating the display device 10 according to one embodiment layer will be described referring to the drawings.

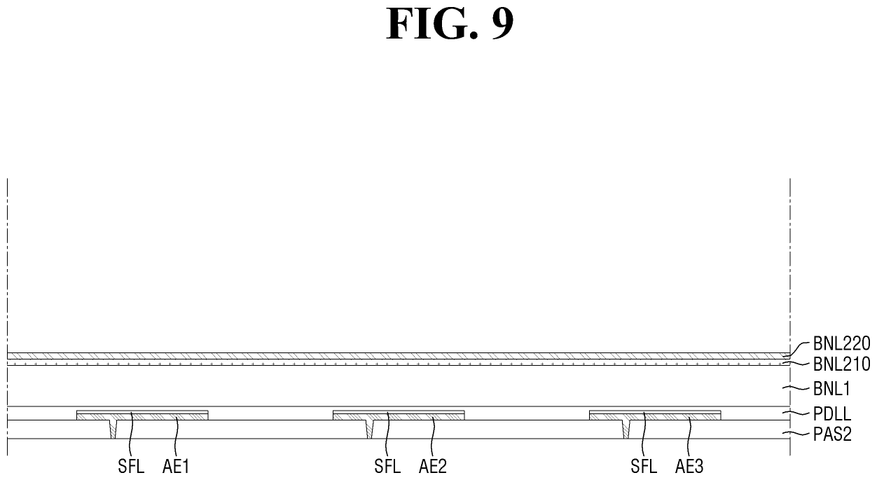

FIGS. 9 to 16 are schematic cross-sectional views sequentially illustrating a method for fabricating a display device according to one embodiment. FIGS. 9 to 16 schematically illustrate a process of forming a bank structure BNS as a light emitting element layer EML of the display device 10, light emitting elements ED and a thin film encapsulation layer TFEL. Hereinafter, a process of forming each layer in a fabricating process of the display device 10 will be omitted, and a formation order of each layer will be described.

Referring to FIG. 9, multiple pixel electrodes AE1, AE2 and AE3 which are spaced apart entirely from each other, a sacrificial layer SFL, a pixel defining material layer PDLL and multiple bank material layers BNL1, BNL210 and BNL220 may be formed on a second passivation layer PAS2.

A second bank material layer may have a multi-layer structure and include a first material layer BN210 and a second material layer BN220. The first material layer BN210 and the second material layer BN220 may form the second bank BN2 after processing. Forming the multi-layered second bank material layer on the first bank material layer BNL1 may include forming the first material layer BN210 including titanium and forming the second material layer BN220 including diamond-like carbon (DLC) or tungsten carbide. FIGS. 9 to 16 illustrate forming the second material layer BN220 after forming the first material layer BN210, but the disclosure is not limited thereto, and in another embodiment, the first material layer BN210 may be formed after forming the second material layer 210. In one embodiment, the forming the first material layer BN210 including titanium may use chemical vapor deposition (CVD) method, the forming the second material layer BN220 including diamond-like carbon (DLC) may use sputtering process, and forming the second material layer BN220 including tungsten carbide may use chemical vapor deposition (CVD) method.

Although not shown, the thin film transistor layer TFTL may be disposed on a substrate SUB, and a structure of the thin film transistor layer TFTL is the same as that described above with reference to FIG. 4. A detailed description of the thin film transistor layer TFTL will be omitted.

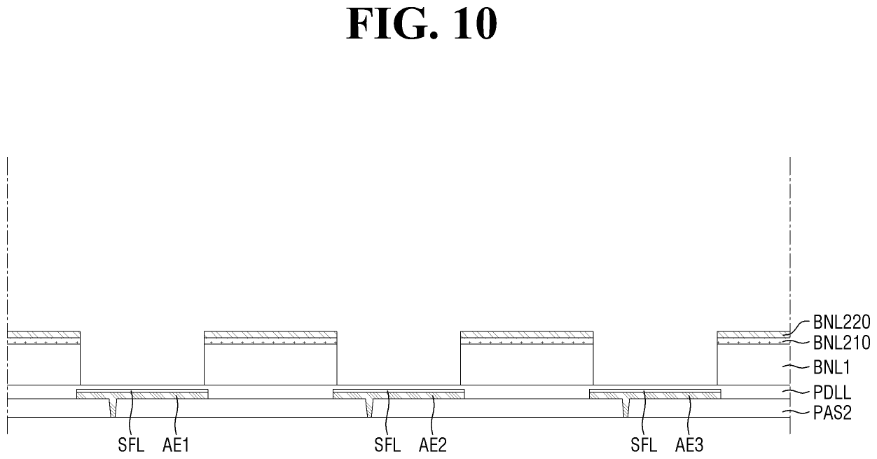

Subsequently, referring to FIG. 10, a first etching process of forming a photoresist (not shown) on the second bank material layer BNL2 and etching parts of the first and second bank material layers BNL1, BNL210, and BNL220 using the photoresist as a mask pattern may be performed. Through the first etching process, holes may be formed in areas not covered by the mask pattern, and a portion of the pixel defining material layer PDLL may be exposed. The photoresist may be arranged to be spaced apart from each other on the second bank material layer BNL2 and may be arranged to expose an area overlapping the pixel electrodes AE1, AE2 and AE3 in a plan view.

In an embodiment, the first etching process may be performed by anisotropic dry etching. The hole may be formed in an area overlapping the pixel electrodes AE1, AE2 and AE3 in a plan view, and the hole may form an opening of the bank structure BNS.

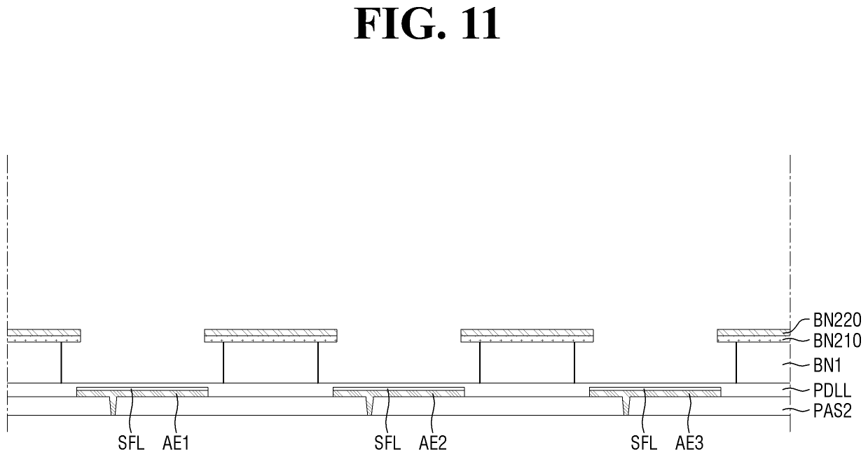

Referring to FIG. 11, an undercut structure of the first bank BN1 may be formed through a second etching process. The first bank material layer BNL1 may have an etch rate faster than the second bank material layer BNL2, and the side of the second bank BN2 may be formed in a structure that protrudes more than the side of the first bank BN1. The side surface of the second bank BN2 may protrude more than the side of the first bank BN1 toward the hole to form a tip TIP, and an undercut may be formed at the bottom.

In one embodiment, the second etching process may be isotropic wet etching. The second etching process may use an alkaline etchant. The bank structure BNS of the first and second banks BN1 and BN2 may be obtained through the second etching process.

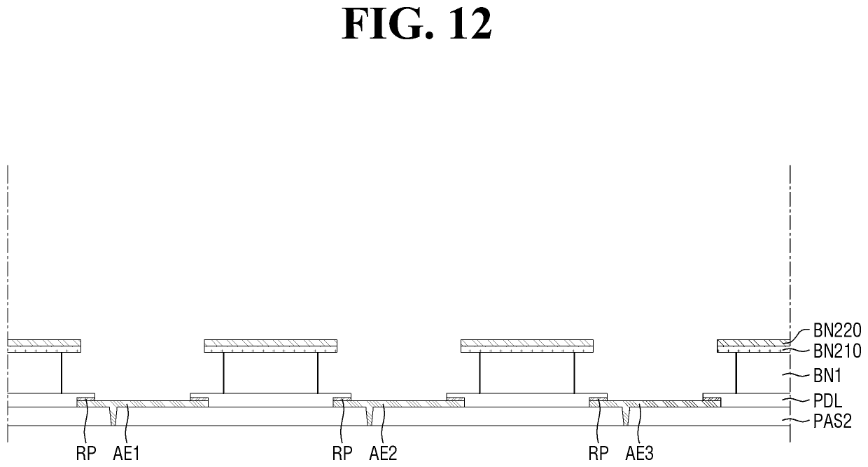

Subsequently, as shown in FIG. 12, the pixel defining material layer PDLL may be removed and the sacrificial layer SFL may also be removed through a third etching process. The third etching process may include an etching that removes the pixel defining material layer PDLL and an etching that removes the sacrificial layer SFL.

The sacrificial layer SFL may protect the pixel electrodes AE1, AE2 and AE3 from plasma in the etching process. In the sacrificial layer SFL, the portion exposed by the hole and a portion between the first bank material layer BNL1 and the pixel electrodes AE1, AE2 and AE3 may be removed. However, the sacrificial layer SFL may not be entirely removed, and a portion of the residual pattern RP may remain between the pixel defining layer PDL and the pixel electrodes AE1, AE2 and AE3. The pixel electrodes AE1, AE2 and AE3 may be exposed through the third etching process.

Through the process of FIGS. 9 to 12, the pixel electrodes AE1, AE2 and AE3 spaced apart from each other on a substrate, the pixel defining layer PDL exposing the pixel electrodes, the first bank BN1 disposed on the pixel defining layer PDL, and the second bank BN2 protruding more than the side of the first bank BN1 may be formed.

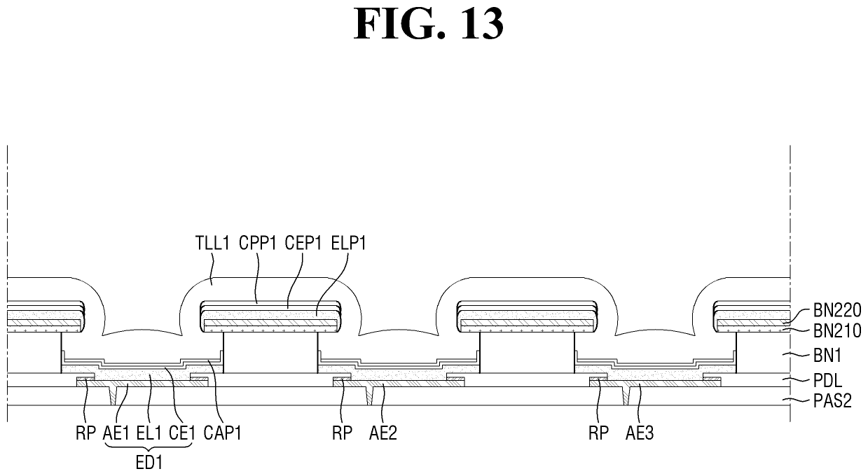

Subsequently, as shown in FIG. 13, the first light emitting element ED1 may be formed by sequentially stacking the first light emitting layer EL1 and the first common electrode CE1 on the first pixel electrode AE1, and the first capping layer CAP1 may be formed on the first common electrode CE1. Since the first light emitting layer EL1, the first common electrode CE1, and the first capping layer CAP1 are formed on the entire surface of the substrate, a first light emitting pattern layer ELP1, a first electrode pattern layer CEP1 and a first capping pattern layer CPP1 may be formed. The first light emitting pattern layer ELP1 and the first light emitting layer EL1 may include a same material, the first electrode pattern layer CEP1 and the first common electrode CE1 may include a same material, and the first capping pattern layer CPP1 and the first capping layer CAP1 may include a same material.

The first light emitting layer EL1 and the first light emitting pattern layer ELP1 may be separated, the first common electrode CE1 and the first electrode pattern layer CEP1 may be separated, and the first capping layer CAP1 and the first capping pattern layer CPP1 may be separated by the tip TIP of the second bank BN2. At the same time as forming the first light emitting layer EL1 on the first pixel electrode AE1, the first light emitting pattern layer ELP1 may be formed on the second bank BN2. At the same time as forming the first common electrode CE1 on the first light emitting layer EL1, the first electrode pattern layer CEP1 may be formed on the first light emitting pattern layer ELP1.

The first light emitting layer EL1 and the first common electrode CE1 may be formed through a thermal deposition process. Deposition of material may not be smooth in the opening due to the tip TIP of the second bank BN2. However, since the materials of the first light emitting layer EL1 and the first common electrode CE1 are deposited in an inclined direction rather than perpendicular direction to the upper surface of the substrate, deposition may also take place in the area covered by the tip TIP of the second bank BN2.

The deposition process for forming the common electrodes CE1, CE2, and CE3 may be performed tilted to be relatively closer to a horizontal direction than the deposition process for forming the light emitting layers EL1, EL2 and EL3. Accordingly, the common electrodes CE1, CE2, and CE3 may have a larger contact area with the side of the first bank BN1 than the light emitting layers EL1, EL2 and EL3. In an embodiment, the common electrodes CE1, CE2, and CE3 may be deposited to a higher position on the side of the first bank BN1 than the light emitting layers EL1, EL2 and EL3. Different common electrodes CE1, CE2, and CE3 may be electrically connected to each other by contacting the first bank BN1 having high conductivity.

Subsequently, a first inorganic material layer TLL1 covering the first capping layer CAP1 and the first capping pattern layer CPP1 may be formed. In one embodiment, the first inorganic material layer TLL1 may be formed through chemical vapor deposition (CVD) method.

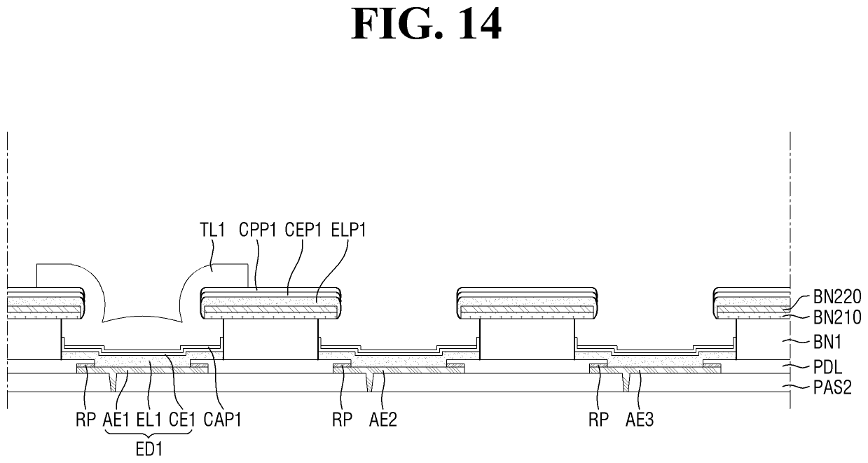

Referring to FIG. 14, a fourth etching process may be performed to remove a portion of the first inorganic material layer TLL1 to expose the first electrode pattern layer CEP1. A photoresist (not shown) as a mask may be formed in an area overlapping the first emission area EA1 in a plan view and the edge area in the periphery thereof, and the first inorganic material layer TLL1 not covered by the mask may be removed. Through the fourth etching process, the first inorganic layer TL1 may remain in the area overlapping the first emission area EA1 and the edge area in the periphery thereof. In an embodiment, the fourth etching process may be anisotropic dry etching.

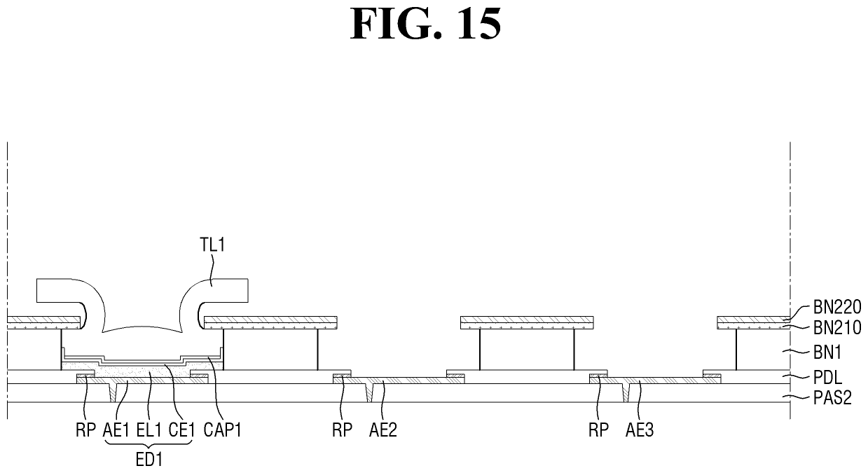

Referring to FIG. 15, a fifth etching process may be performed to expose the second bank BN2 by removing the first capping pattern layer CPP1, the first electrode pattern layer CEP1, and the first light emitting pattern layer ELP1 to expose the second bank BN2. In an embodiment, the fifth etching process may include an isotropic wet etching step. Not only the first capping pattern layer CPP1, the first electrode pattern layer CEP1, and the first light emitting pattern layer ELP1 disposed on the second bank BN2, but the first light emitting pattern layer ELP1, the first electrode pattern layer CEP1, and the first capping pattern layer CPP1 of the second and third emission areas EA2 and EA3 not covered by the first inorganic material layer TLL1 may be removed. Accordingly, the first light emitting pattern layer ELP1, the first electrode pattern layer CEP1, and the first capping pattern layer CPP1 disposed between the first inorganic layer TL1 and the second bank BN2 may be removed and an undercut structure of the first inorganic layer TL1 may be formed.

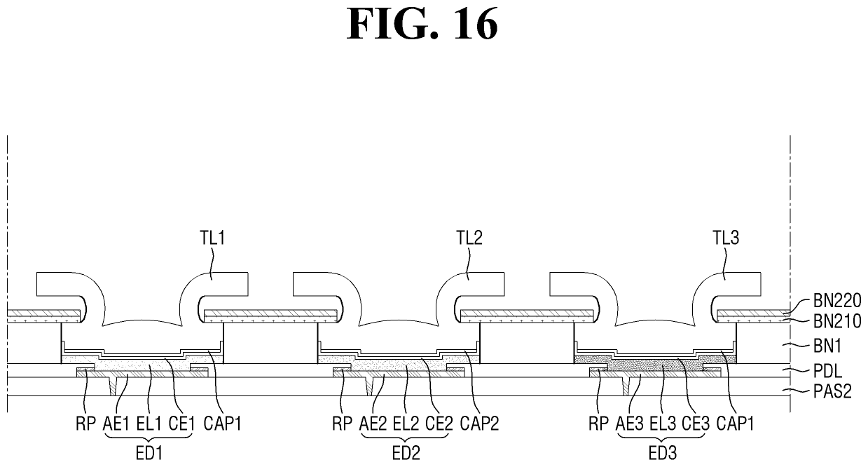

Referring to FIG. 16, by performing the process as shown in FIGS. 13 to 15, the second light emitting element ED2 and the second inorganic layer TL2 may be formed on the second emission area EA2 and the third light emitting element ED3 and the third inorganic layer TL3 may be formed on the third emission area EA3.

Subsequently, although not illustrated in the drawings, the display device 10 may be fabricated by forming the organic encapsulation layer TFE2 of the thin film encapsulation layer TFEL, the upper inorganic encapsulation layer TFE3, the color filter layer CFL, and the overcoat layer OC on the light emitting elements ED1, ED2, and ED3 and the bank structure BNS. Structures of the thin film encapsulation layer TFEL, the color filter layer CFL, and the overcoat layer OC are the same as those described above, and a detailed description thereof will thus be omitted.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel electrode disposed on a substrate;
a pixel defining layer disposed on the substrate and exposing the pixel electrode;
a light emitting layer disposed on the pixel electrode;
a common electrode disposed on the light emitting layer;
a first bank disposed on the pixel defining layer; and
a second bank disposed on the first bank and having a side protruding more than a side of the first bank,
wherein the second bank comprises a first layer having a modulus less than about 300 GPa and a second layer having a modulus equal to or greater than about 300 GPa.

2. The display device of claim 1, wherein a difference between the modulus of the first layer of the second bank and the modulus of the second layer of the second bank is in a range of about 350 GPa to about 800 GPa.

3. The display device of claim 1, wherein the side of the first layer of the second bank and the side of the second layer of the second bank are aligned.

4. The display device of claim 1, wherein a sum of thicknesses of the first layer and the second layer is less than about 2400 Å.

5. The display device of claim 1, wherein a thickness of the first layer of the second bank is about 0.5 to about 2 times of a thickness of the second layer of the second bank.

6. The display device of claim 1, wherein
a thickness of the first layer of the second bank is in a range of about 500 Å to about 1200 Å, and
a thickness of the second layer of the second bank is in a range of about 300 Å to about 1200 Å.

7. The display device of claim 1, wherein
the first layer comprises titanium, and
the second layer comprises diamond-like carbon (DLC) or tungsten carbide.

8. The display device of claim 1, wherein
the first layer of the second bank is disposed on the first bank, and
the second layer of the second bank is disposed on the first layer of the second bank.

9. The display device of claim 8, wherein the second bank further comprises a third layer disposed between the first layer and the second layer and comprises titanium oxide.

10. The display device of claim 9, wherein a thickness of the third layer of the second bank is less than a thickness of the first layer and the second layer of the second bank.

11. The display device of claim 9, wherein a thickness of the third layer of the second bank is in a range of about 50 Å to about 200 Å.

12. The display device of claim 1, wherein
the second layer of the second bank is disposed on the first bank, and
the first layer of the second bank is disposed on the second layer of the second bank.

13. The display device of claim 1, further comprising:
a first inorganic layer disposed on an upper surface and a lower surface of the second bank and on the common electrode.

14. The display device of claim 13, wherein the first inorganic layer is spaced apart from the upper surface of the second bank.

15. The display device of claim 14, further comprising:
an organic encapsulation layer disposed in a space between the first inorganic layer and the upper surface of the second bank.

16. The display device of claim 15, wherein the second bank, the organic encapsulation layer, and the first inorganic layer are sequentially stacked in an area overlapping the second bank and the first inorganic layer in a plan view.

17. A method for fabricating a display device, the method comprising:
forming a plurality of pixel electrodes spaced apart from each other and a pixel defining layer exposing the plurality of pixel electrodes;
forming a first bank material layer on the pixel defining layer;
forming a multi-layered second bank material layer on the first bank material layer;
etching a portion of the multi-layered second bank material layer and the first bank material layer;
etching a side of the first bank material layer to expose a lower surface of the multi-layered second bank material layer;
forming a light emitting layer on one of the plurality of pixel electrodes;
forming a light emitting pattern layer on the multi-layered second bank material layer;
forming a common electrode on the light emitting layer;
forming an electrode pattern layer on the light emitting pattern layer;
forming an inorganic material layer on the electrode pattern layer;
etching a portion of the inorganic material layer; and
etching the light emitting pattern layer and the electrode pattern layer to expose the multi-layered second bank material layer.

18. The method of claim 17, wherein the forming of the multi-layered second bank material layer on the first bank material layer comprises:
forming a first material layer comprising titanium; and
forming a second material layer comprising diamond-like carbon (DLC) or tungsten carbide.

19. The method of claim 18, wherein the etching of the portion of the multi-layered second bank material layer and the first bank material layer comprises:
forming a mask pattern on the multi-layered second bank material layer; and
etching the multi-layered second bank material layer and the first bank material layer not covered by the mask pattern through a dry-etching process.

20. The method of claim 18, wherein the etching of the light emitting pattern layer and the electrode pattern layer comprises removing the light emitting pattern layer and the electrode pattern layer between the multi-layered second bank material layer and the inorganic material layer.
